(19) United States
(12) Patent Application Publication
(10) Pub. No.: US 2017/0263562 A1
(43) Pub. Date: Sep. 14, 2017

(54) SEMICONDUCTOR DEVICE AND METHOD OF MANUFACTURING THE SAME

(71) Applicant: KABUSHIKI KAISHA TOSHIBA, Tokyo (JP)

(72) Inventors: Tatsuro SAITO, Yokkaichi (JP); Atsunobu ISOBAYASHI, Yokkaichi (JP); Akihiro KAJITA, Yokkaichi (JP)

(73) Assignee: KABUSHIKI KAISHA TOSHIBA, Tokyo (JP)

(21) Appl. No.: 15/266,626

(22) Filed: Sep. 15, 2016

(30) Foreign Application Priority Data
Mar. 14, 2016 (JP) 2016-049710

(51) Int. Cl. H01L 23/532; H01L 21/3205; H01L 21/768; H01L 23/528; H01L 23/522

(52) U.S. Cl. CPC H01L 23/53276; H01L 23/528; H01L 23/5226; H01L 21/76802; H01L 21/76843; H01L 21/76877; H01L 21/32055

(57) ABSTRACT

According to one embodiment, a semiconductor device is disclosed. The device includes a substrate, and a first interconnect on the substrate. The first interconnect includes a first catalyst layer capable of growing graphene, a graphene layer in contact with a side surface of the first catalyst layer. The device further includes a non-catalyst layer in contact with a bottom surface of the graphene layer, and incapable of growing graphene.

### CROSS-REFERENCE TO RELATED APPLICATIONS

This application is based upon and claims the benefit of priority from Japanese Patent Application No. 2016-049710, filed Mar. 14, 2016, the entire contents of which are incorporated herein by reference.

### FIELD

Embodiments described herein relate generally to a semiconductor device which includes an interconnect employing a graphene layer (a graphene interconnect) and a method of manufacturing the same.

### BACKGROUND

In recent years, miniaturization of interconnects has advanced in LSI interconnect structures. The miniaturization brings about problems such as an increasing of electric resistivity caused by interfacial inelastic scattering of electrons, an increasing of current density, and a reliability degradation due to stress migration or electromigration. To solve these problems, copper is mainly used as an LSI interconnect material, which is a low-resistance metal.

### BRIEF DESCRIPTION OF THE DRAWINGS

FIG. 1 is a plan view illustrating a semiconductor device according to a first embodiment.

FIG. 2A is a sectional view taken along dashed-dotted line 2A-2A of FIG. 1.

FIG. 2B is a sectional view taken along dashed-dotted line 2B-2B of FIG. 1.

FIG. 2C is a sectional view taken along dashed-dotted line 2C-2C of FIG. 1.

FIG. 3 is a plan view illustrating a method of manufacturing the semiconductor device according to the first embodiment.

FIG. 4A is a sectional view taken along dashed-dotted line 4A-4A of FIG. 3.

FIG. 4B is a sectional view taken along dashed-dotted line 4B-4B of FIG. 3.

FIG. 4C is a sectional view taken along dashed-dotted line 4C-4C of FIG. 3.

FIG. 5 is a plan view, subsequent to FIG. 3, illustrating the method of manufacturing the semiconductor device according to the first embodiment.

FIG. 6A is a sectional view taken along dashed-dotted line 6A-6A of FIG. 5.

FIG. 6B is a sectional view taken along dashed-dotted line 6B-6B of FIG. 5.

FIG. 6C is a sectional view taken along dashed-dotted line 6C-6C of FIG. 5.

FIG. 7 is a plan view, subsequent to FIG. 5, illustrating the method of manufacturing the semiconductor device according to the first embodiment.

FIG. 8A is a sectional view taken along dashed-dotted line 8A-8A of FIG. 7.

FIG. 8B is a sectional view taken along dashed-dotted line 8B-8B of FIG. 7.

FIG. 80 is a sectional view taken along dashed-dotted line 8C-8C of FIG. 7.

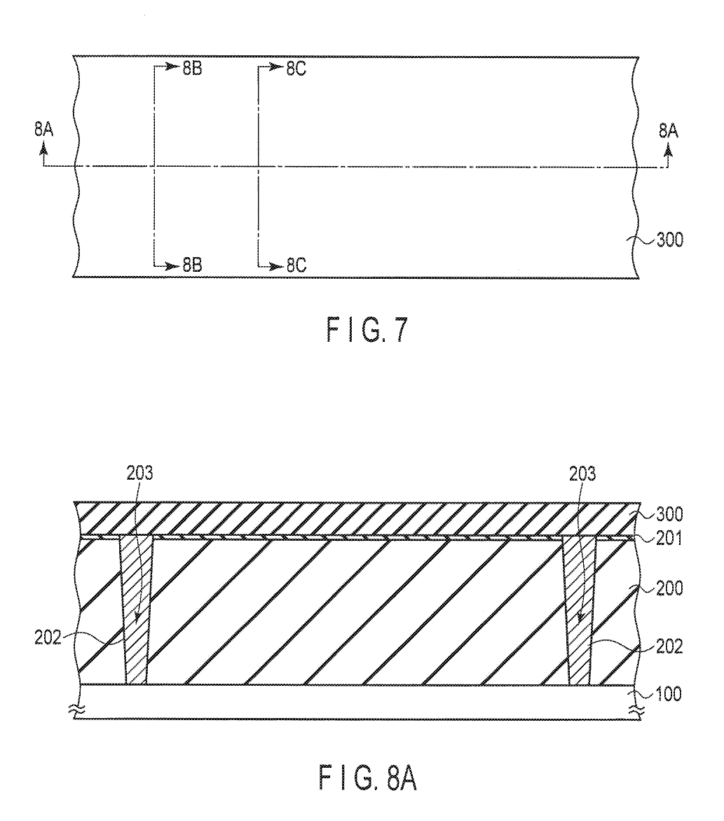

FIG. 9 is a plan view, subsequent to FIG. 7, illustrating the method of manufacturing the semiconductor device according to the first embodiment.

FIG. 10A is a sectional view taken along dashed-dotted line 10A-10A of FIG. 9.

FIG. 10B is a sectional view taken along dashed-dotted line 10B-10B of FIG. 9.

FIG. 100 is a sectional view taken along dashed-dotted line 10C-10C of FIG. 9.

FIG. 11 is a plan view, subsequent to FIG. 9, illustrating the method of manufacturing the semiconductor device according to the first embodiment.

FIG. 12A is a sectional view taken along dashed-dotted line 12A-12A of FIG. 11.

FIG. 12B is a sectional view taken along dashed-dotted line 12B-12B of FIG. 11.

FIG. 12C is a sectional view taken along dashed-dotted line 12C-12C of FIG. 11.

FIG. 13 is a sectional view schematically depicting a structure of a graphene layer within a region surrounded by a broken line in FIG. 12B.

FIG. 14 is a sectional view schematically depicting a progress of growing of a graphene layer on an underlayer which is free from a catalyst function for graphene.

FIG. 15 is a sectional view schematically depicting a graphene layer formed on an underlayer which has a catalyst function for graphene.

FIG. 16 is a plan view illustrating a semiconductor device according to a second embodiment.

FIG. 17A is a sectional view taken along dashed-dotted line 17A-17A of FIG. 16.

FIG. 17B is a sectional view taken along dashed-dotted line 17B-17B of FIG. 16.

FIG. 17C is a sectional view taken along dashed-dotted line 17C-17C of FIG. 16.

FIG. 18 is a sectional view schematically depicting a structure of a graphene layer within a region surrounded by a broken line in FIG. 17B.

FIG. 19 is a plan view depicting a semiconductor according to a third embodiment.

FIG. 20A is a sectional view taken along dashed-dotted line 20A-20A of FIG. 19.

FIG. 20B is a sectional view taken along dashed-dotted line 20B-20B of FIG. 19.

FIG. 20C is a sectional view taken along dashed-dotted line 20C-20C of FIG. 19.

FIG. 20D is a sectional view taken along dashed-dotted line 20D-20D of FIG. 19.

FIG. 21 is a plan view, subsequent to FIG. 19, illustrating the method of manufacturing the semiconductor device according to the third embodiment.

FIG. 22A is a sectional view taken along dashed-dotted line 22A-21A of FIG. 21.

FIG. 22B is a sectional view taken along dashed-dotted line 22B-22B of FIG. 21.

FIG. 22C is a sectional view taken along dashed-dotted line 22C-22C of FIG. 21.

FIG. 22D is a sectional view taken along dashed-dotted line 22D-22D of FIG. 21.

FIG. 23 is a plan view, subsequent to FIG. 21, illustrating the method of manufacturing the semiconductor device according to the third embodiment.

FIG. 24A is a sectional view taken along dashed-dotted line 24A-24A of FIG. 23.

FIG. 24B is a sectional view taken along dashed-dotted line 24B-24B of FIG. 23.

FIG. 24C is a sectional view taken along dashed-dotted line 24C-24C of FIG. 23.

FIG. 24D is a sectional view taken along dashed-dotted line 24D-24D of FIG. 23.

FIG. 25 is a plan view, subsequent to FIG. 23, illustrating the method of manufacturing the semiconductor device according to the third embodiment.

FIG. 26A is a sectional view taken along dashed-dotted line 26A-26A of FIG. 25.

FIG. 26B is a sectional view taken along dashed-dotted line 26B-26B of FIG. 25.

FIG. 26C is a sectional view taken along dashed-dotted line 26C-26C of FIG. 25.

FIG. 26D is a sectional view taken along dashed-dotted line 26D-26D of FIG. 25.

FIG. 27 is a plan view, subsequent to FIG. 25, illustrating the method of manufacturing the semiconductor device according to the third embodiment.

FIG. 28A is a sectional view taken along dashed-dotted line 28A-28A of FIG. 27.

FIG. 28B is a sectional view taken along dashed-dotted line 28B-28B of FIG. 27.

FIG. 28C is a sectional view taken along dashed-dotted line 28C-28C of FIG. 27.

FIG. 28D is a sectional view taken along dashed-dotted line 28D-28D of FIG. 27.

FIG. 29 is a plan view illustrating a semiconductor device according to a fourth embodiment.

FIG. 30A is a sectional view taken along dashed-dotted line 30A-30A of FIG. 29.

FIG. 30B is a sectional view taken along dashed-dotted line 30B-30B of FIG. 29.

FIG. 30C is a sectional view taken along dashed-dotted line 30C-30C of FIG. 29.

FIG. 31 is a plan view illustrating a method of manufacturing the semiconductor device according to the fourth embodiment.

FIG. 32A is a sectional view taken along dashed-dotted line 32A-32A of FIG. 31.

FIG. 32B is a sectional view taken along dashed-dotted line 32B-32B of FIG. 31.

FIG. 32C is a sectional view taken along dashed-dotted line 32C-32C of FIG. 31.

FIG. 33 is a plan view, subsequent to FIG. 31, illustrating the method of manufacturing the semiconductor device according to the fourth embodiment.

FIG. 34A is a sectional view taken along dashed-dotted line 34A-34A of FIG. 33.

FIG. 34B is a sectional view taken along dashed-dotted line 34B-34B of FIG. 33.

FIG. 34C is a sectional view taken along dashed-dotted line 34C-34C of FIG. 33.

FIG. 35 is a plan view, subsequent to FIG. 33, illustrating the method of manufacturing the semiconductor device according to the fourth embodiment.

FIG. 36A is a sectional view taken along dashed-dotted line 36A-36A of FIG. 35.

FIG. 36B is a sectional view taken along dashed-dotted line 36B-36B of FIG. 35.

FIG. 36C is a sectional view taken along dashed-dotted line 36C-36C of FIG. 35.

### DETAILED DESCRIPTION

In general, according to one embodiment, a semiconductor device is disclosed. The device includes a substrate, and a first interconnect on the substrate. The first interconnect includes a first catalyst layer capable of growing graphene, a graphene layer in contact with a side surface of the first catalyst layer. The device further includes a non-catalyst layer in contact with a bottom surface of the graphene layer, and incapable of growing graphene.

According to another embodiment, a method of manufacturing a semiconductor device is disclosed. The method includes forming a non-catalyst layer on the substrate, forming a through hole in the non-catalyst layer. The method further includes forming a catalyst layer for graphene growth, on a region corresponding to the through hole of the non-catalyst layer; and forming a graphene layer on an upper surface of the non-catalyst layer.

Embodiments will be described hereinafter with reference to the accompanying drawings. The drawings are merely schematic and conceptual diagrams, and the dimensions of elements shown, the rations between the elements and the like in the drawings are not necessarily the same as those of actual implementations of the embodiments. Further, in the drawings, identical or corresponding portions are denoted by the same reference numerals, and their repetitive description will be repeated when necessary. In addition, as used in the description and the appended claims, the singular forms “a”, “an”, and “the” are intended to include the plural forms as well, unless the context clearly indicates otherwise.

### First Embodiment

As mentioned above, copper is a low-resistance metal. However, if the interconnects are further miniaturized, the above-described problems may be caused even copper is employed.

Graphene exhibits quantized conductance (what is called Ballistic conductance), and may be an extremely low resistance material as an alternative to the existing metallic materials. In view of this, an interconnect comprising graphene (graphene interconnect) is used as an LSI interconnect in the following embodiments. It is noted that a copper interconnect or an aluminum interconnect may be used together with the graphene interconnect in the semiconductor device.

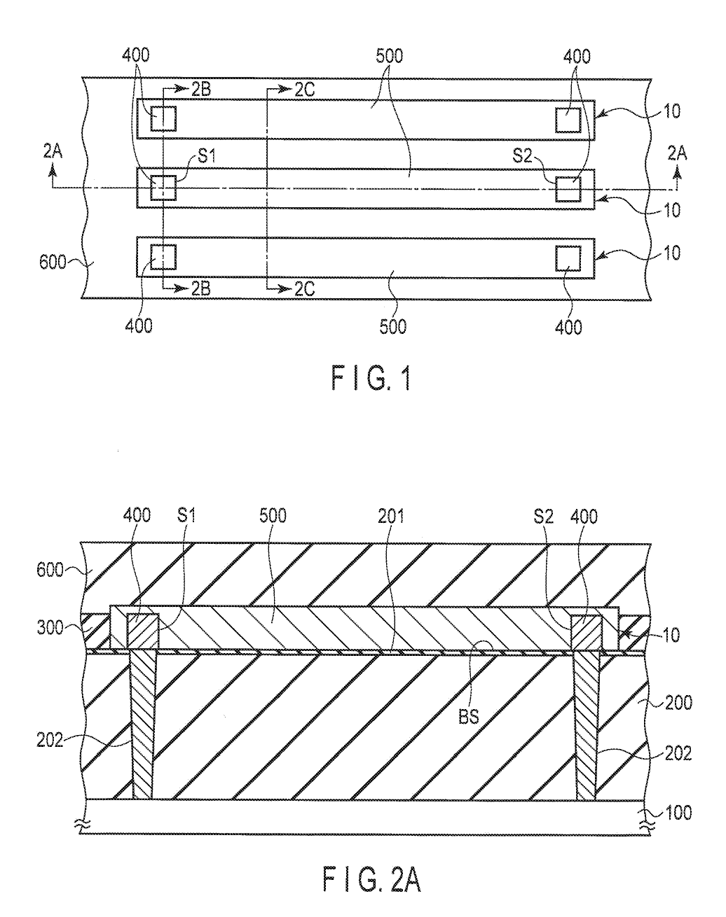

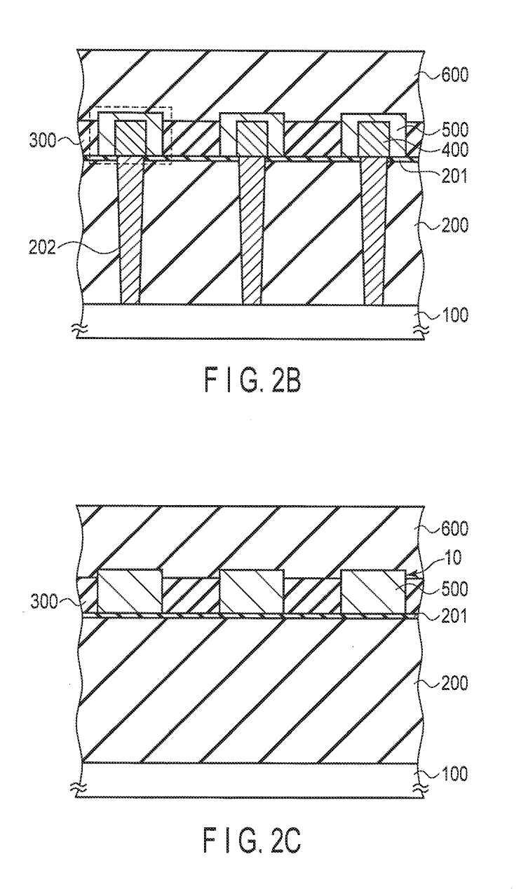

FIG. 1 is a plan view illustrating a semiconductor device according to a first embodiment. FIGS. 2A, 2B and 2C are sectional views taken along dashed-dotted lines 2A-2A, 2B-2B and 2C-2C of FIG. 1, respectively.

The semiconductor device of the present embodiment comprises graphene interconnects 10. Three linear graphene interconnects 10 are depicted in FIG. 1 by way of example. The number of graphene interconnect(s) 10 may be one, two, or more than three. The graphene interconnects 10 are arranged along a direction perpendicular to a longitudinal direction of the graphene interconnects 10.

Each graphene interconnect 10 includes one graphene layer 500, two catalyst layers (a first catalyst layer and a second catalyst layer) 400 and one underlayer (a non-catalyst layer) 201.

The graphene layer 500 is provided between the two catalyst layers 400. The two catalyst layers 400 are connected to each other by the graphene layer 500. The graphene layer 500 is in contact with side surfaces S1 and S2 of the two catalyst layers 400 opposed to each other. The underlayer 201 is provided under the graphene layer 500. The underlayer 201 is in contact with a lower surface of the graphene layer 500.

The graphene layer 500 is also provided in a region other than the region between side surfaces S1 and S2 of the two catalyst layers 400 opposed to each other. The graphene layer 500 in the above-described another region is formed due to a process for growing graphene. That is, in the process, the graphene grows from four side surfaces of catalyst layer 400 illustrated in a plan view of FIG. 9, and the graphene layer 500 is formed in such a manner as to surround the four side surfaces of the catalyst layer 400 illustrated in a plan view of FIG. 11.

Similarly, the underlayer 201 under the graphene layer 500 in the above-described another region is also formed due to the process for growing graphene. That is, in the process, the graphene is grown on an exposed underlayer 201 illustrated in the plan view of FIG. 9. In FIG. 9, the exposed underlayer 201 is categorized into (i) the under layer in a region (first region) between two graphene layers facing in the lateral direction and (ii) the under layer in a region (second region) other than the first region. The graphene layer 500 in the above-described another region is the graphene layer in the second region. Similarly, the underlayer 201 is also provided under a region where the graphene layer 500 does not exist (for example, under the interlayer insulating film 300).

The catalyst layer 400 has a function of catalyst for growing graphene. Note that, in the present disclosure, graphene includes at least one of a monolayer graphene, and a multilayer of monolayer graphene (stacked graphene). In addition, the graphene layer in the embodiments is a layer including the graphene.

The material of the catalyst layer 400 contains, for example, at least one of cobalt (Co), nickel (Ni), iron (Fe), ruthenium (Ru) or copper (Cu), and an alloy containing Co, Ni, Fe, Ru or Cu, and carbide of Co, Ni, Fe, Ru or Cu.

The catalyst layer 400 is a monolayer film or a stacked multilayer film containing the above-described material. In a state where the catalyst layer 400 is dispersed into fine particles, graphene does not grow appropriately, or a graphene layer may be formed discontinuously. Therefore, it is preferable that the catalyst layer 400 be a continuous film.

The distance between the two catalyst layers 400 (the longitudinal dimension of the interconnection 10) is greater than or equal to a mean free path of electrons in graphene, for example, greater than or equal to 0.1 μm, more preferably, greater than or equal to 1 μm. Noted that a single catalyst layer may be used instead of the two graphene layers 400 as long as the single graphene layers 400 enables the graphene to grow into a graphene layer with a length not less than the mean free path.

An upper surface of the catalyst layer 400 is lower than an upper surface of the graphene layer 500 in the present embodiment, but the upper surface of the catalyst layer 400 may be higher than the upper surface of the graphene layer 500. Alternatively, the upper surface of the catalyst layer 400 may be as high as the upper surface of the graphene layer 500.

The catalyst layer 400 has a function for growing graphene. However, the underlayer 201 does not have the function for growing graphene. In the present embodiment, the underlayer 201 has an insulating property. A material of the underlayer 201 includes, for example, oxide of the material of the catalyst layer 400 such as copper oxide or nickel oxide, or metal oxide such as aluminum oxide (for example, Al₂O₃) which is more graphene-adsorptive than silicon oxide.

An interlayer insulating film 600 is provided on the graphene layer 500. The interlayer insulating film 600 may be provided with a plug (not shown) which is in contact with the catalytic layer 400.

In the present embodiment, as illustrated in FIGS. 2A and 2B, the semiconductor device further includes a plurality of plugs. Two plugs (first plug and second plug) 202 are provided for each of the graphene interconnects 10. The two plugs 202 are respectively provided under the two catalyst layers 400 of the graphene interconnect 10, and the upper surfaces of the two plugs 202 are respectively in contact with the lower surfaces of the two catalyst layers 400. More specifically, the upper surfaces of the plugs 202 are respectively in contact with the lower surfaces of the catalyst layers 400 of the graphene interconnect 10.

When employing a method of selective deposition of catalyst material onto a selected area to form the catalyst layer 400, the area of the lower surface of the catalyst layer 400 is approximately same as the area of the upper surface of the plug 202. However, there is no particular relationship between the area of the lower surface of the catalyst layer 400 and the area of the upper surface of the plug 202.

In the present embodiment, a lower surface of the plug 202 is connected to a substrate 100. More specifically, the lower surface of the plug 202 may be connected to a source or drain region of a MOS transistor (not shown) in the substrate 100, for instance. It is noted that the lower surface of the plug 202 may be connected to an element other than the MOS transistor in the substrate 100, for example, a capacitor. In addition, the lower surface of the plug 202 may be connected to a member (not show) such as an interconnect between the substrate 100 and the interconnect 10. The interconnect is, for example, a damascene interconnect which is formed in an interlayer insulating film on the substrate 100.

The semiconductor device of the present embodiment will be further described below in accordance with a method of manufacturing the same.

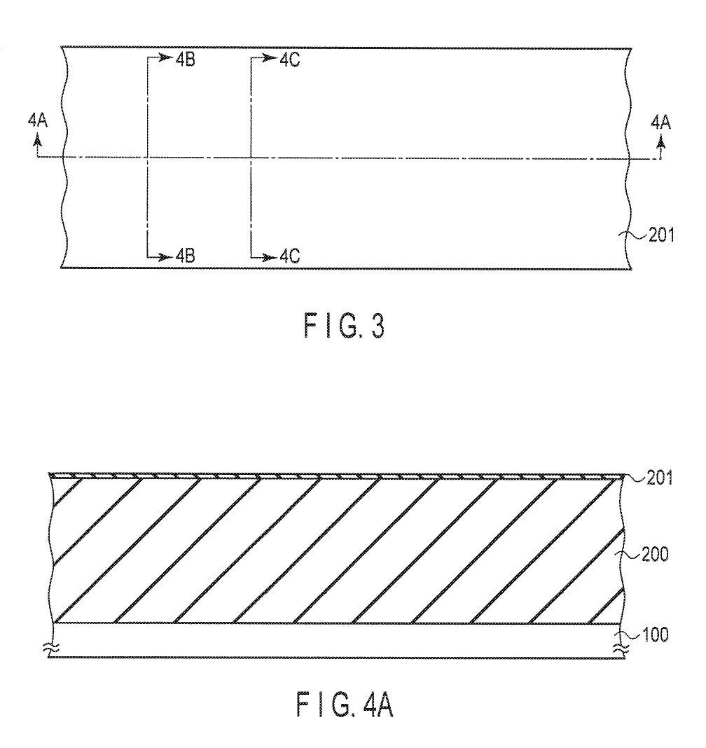

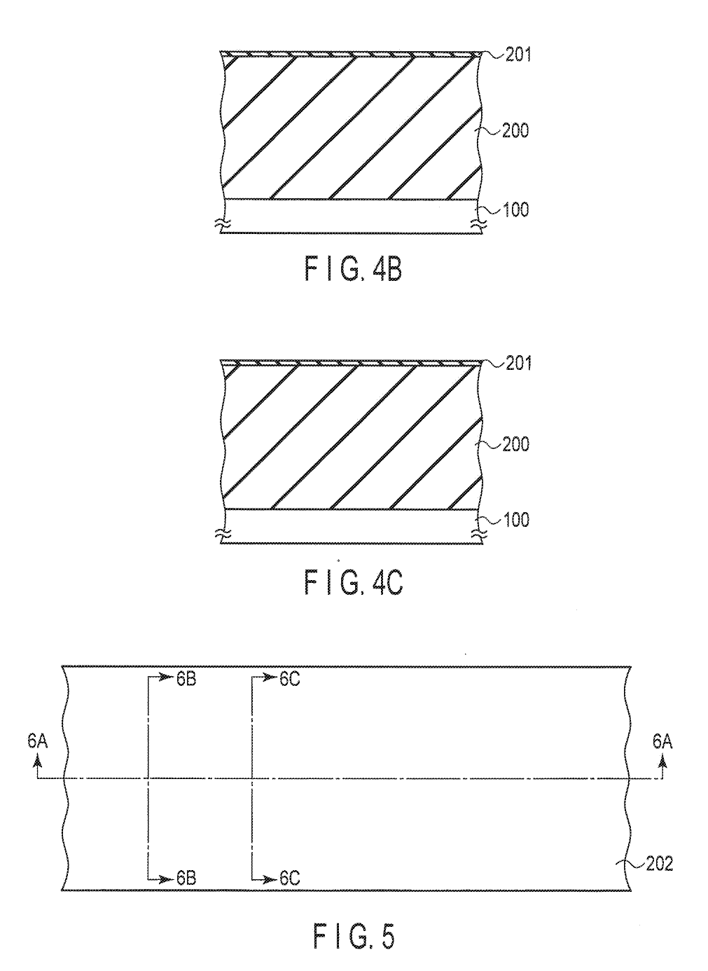

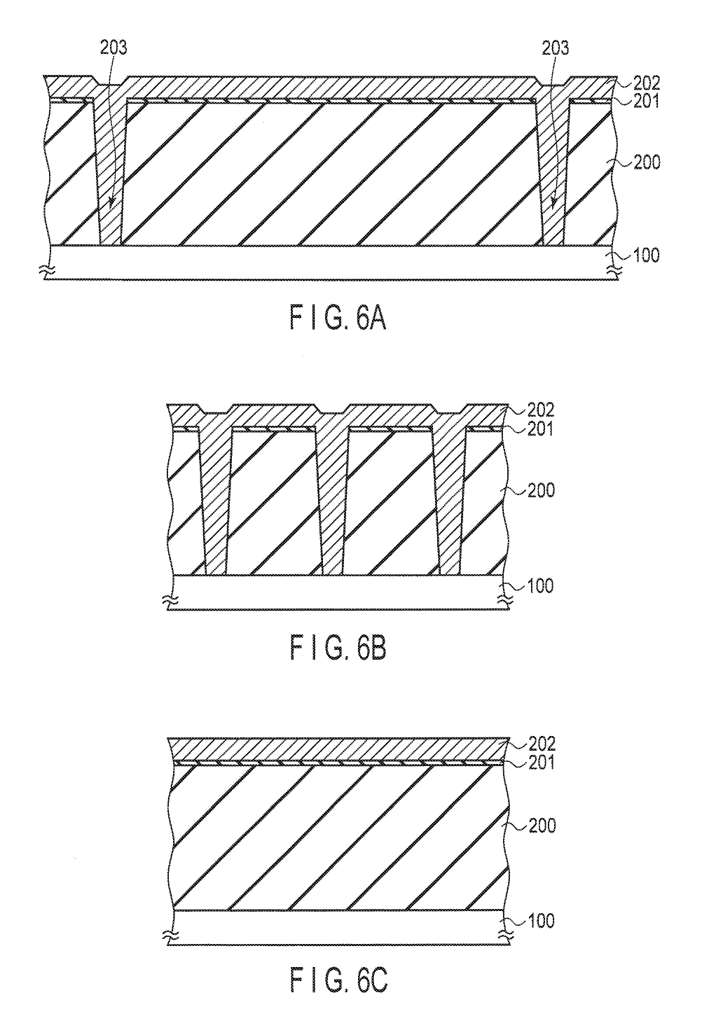

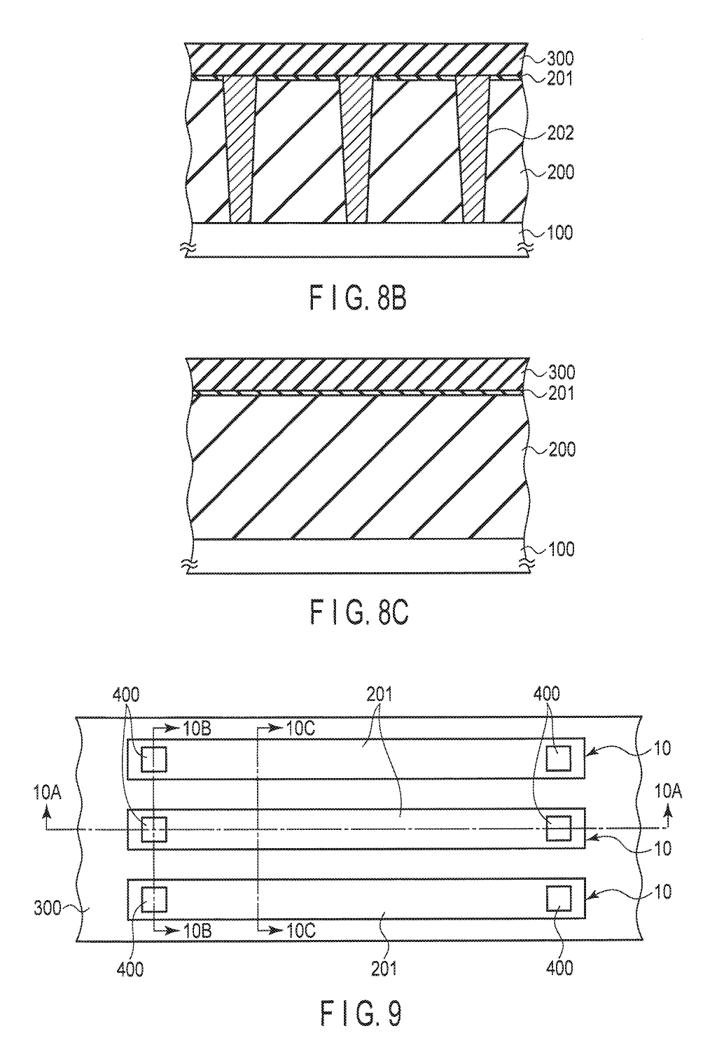

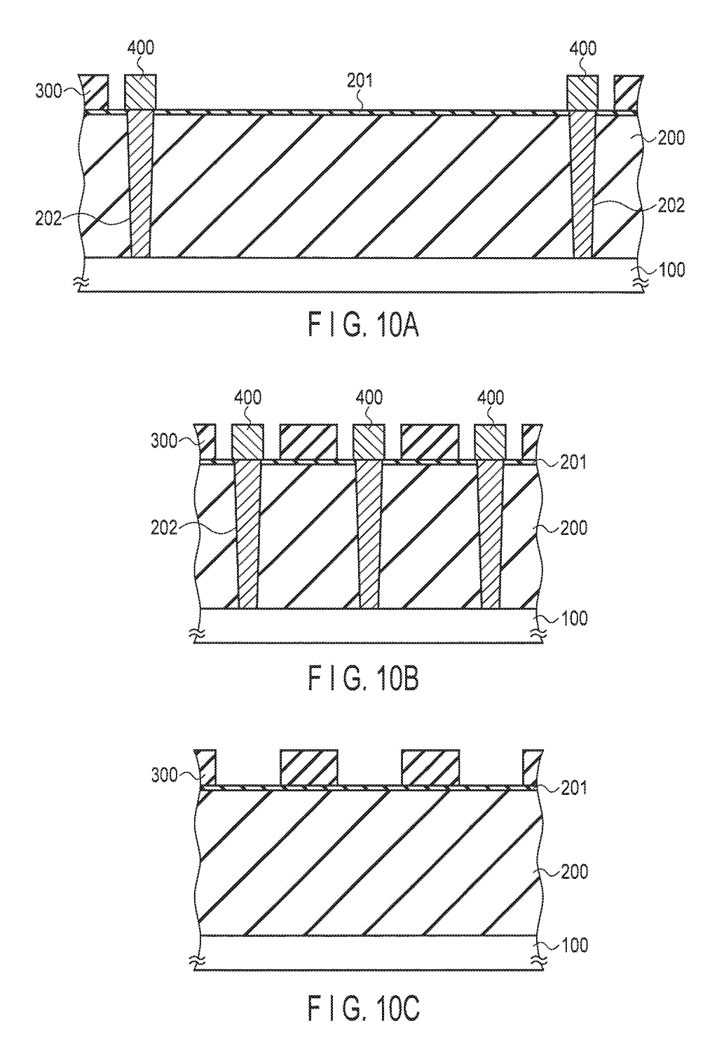

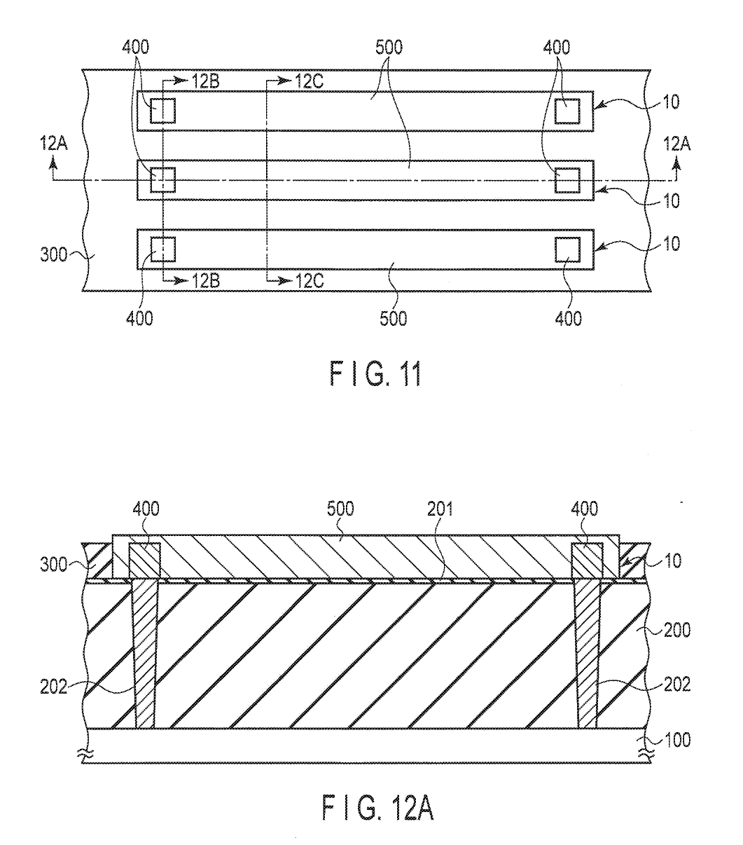

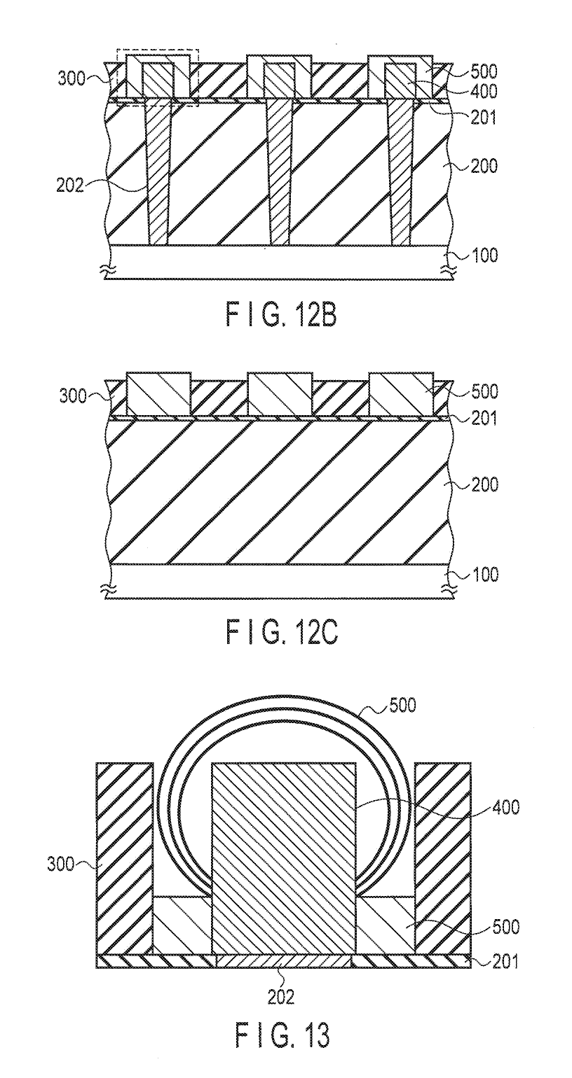

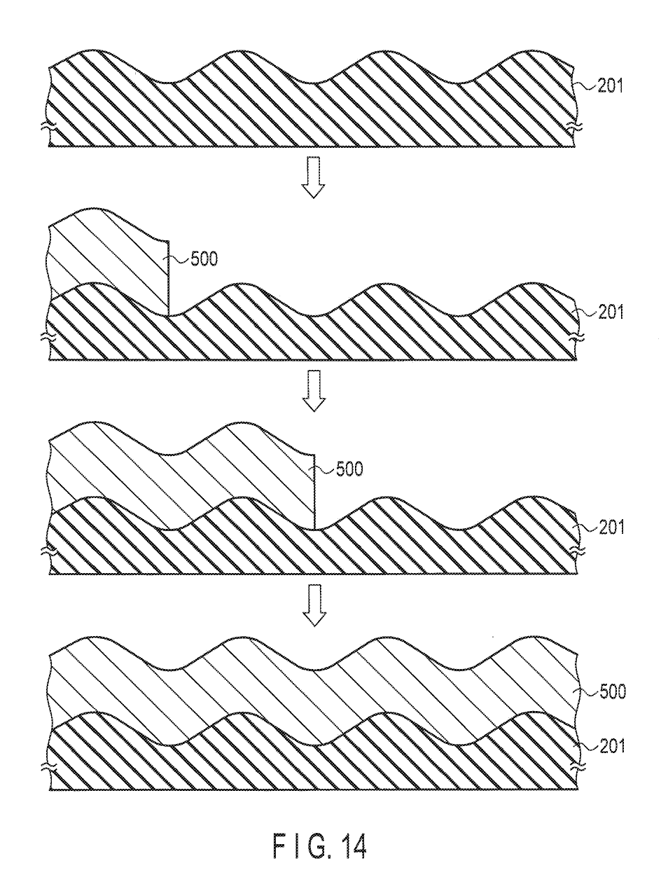

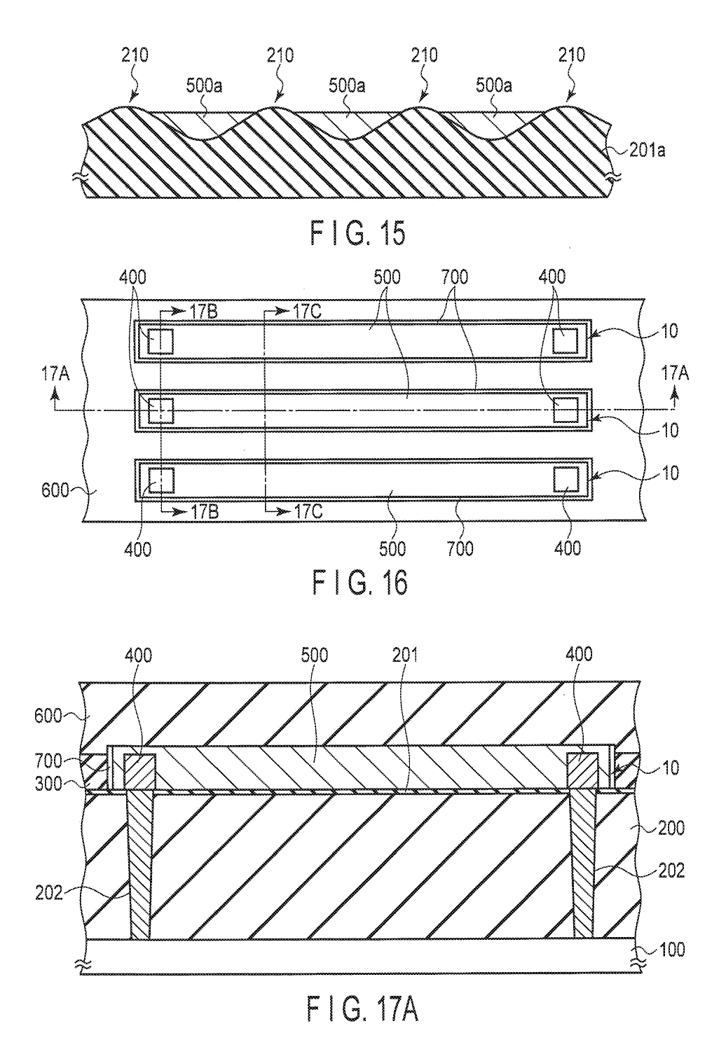

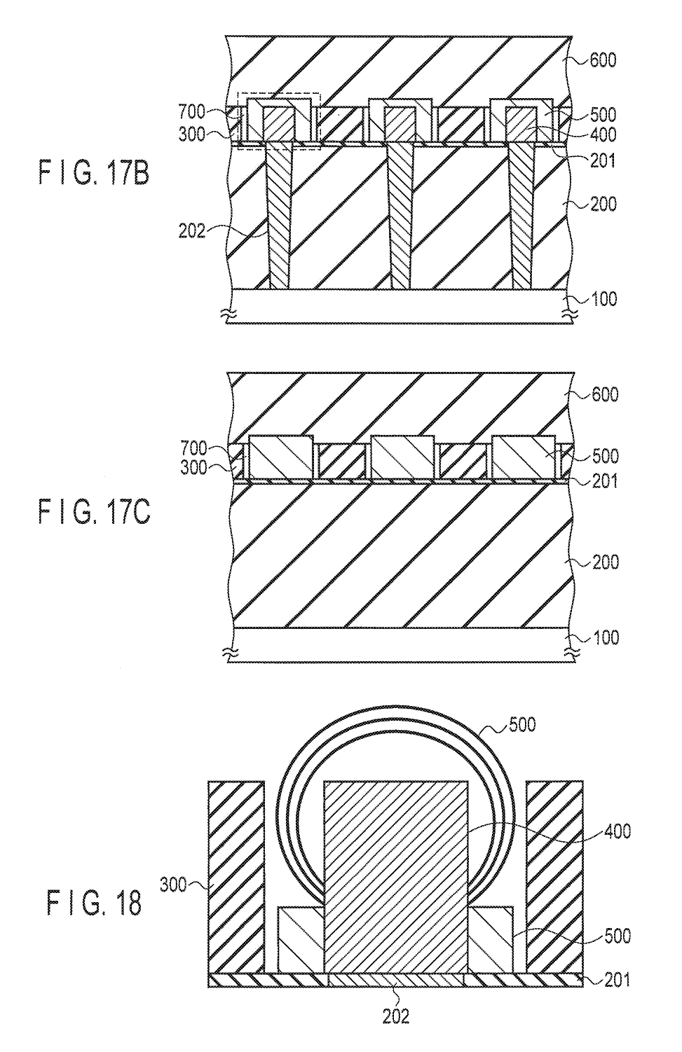

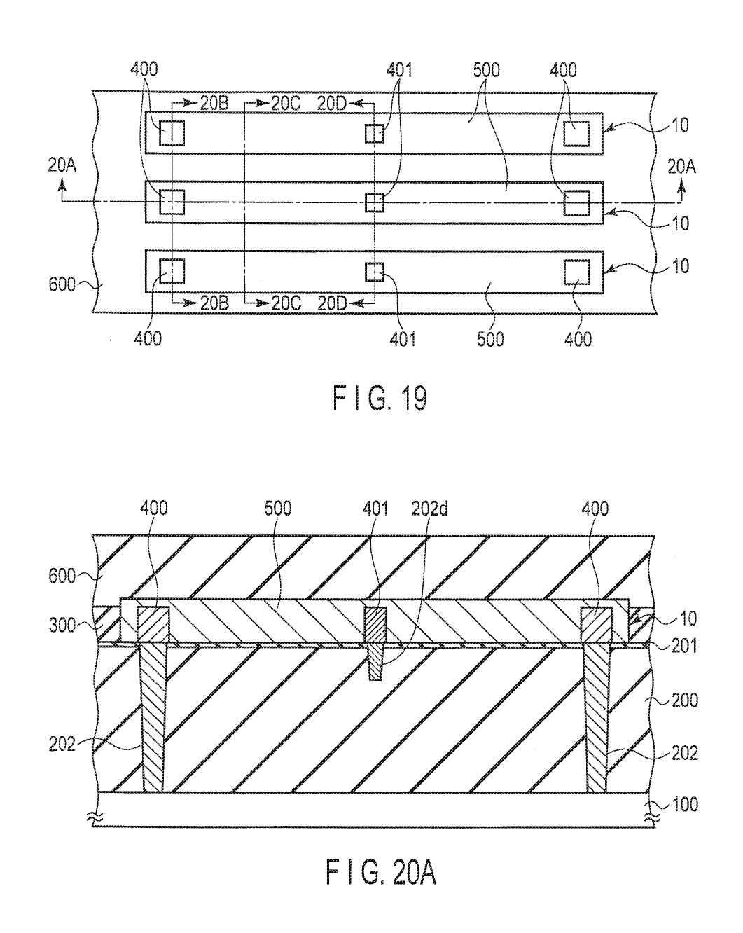

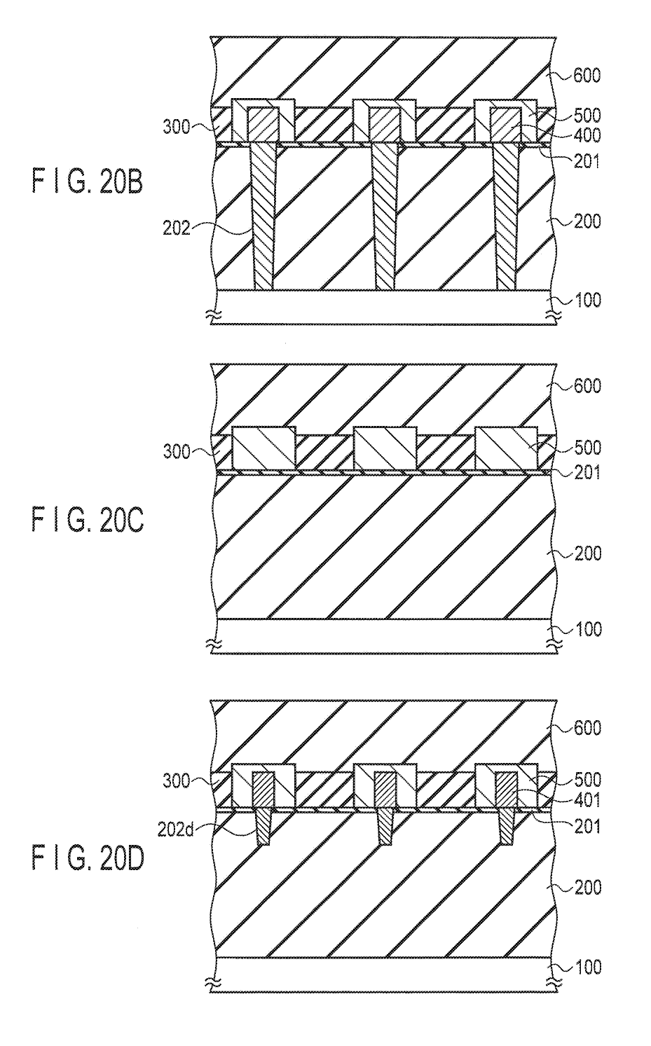

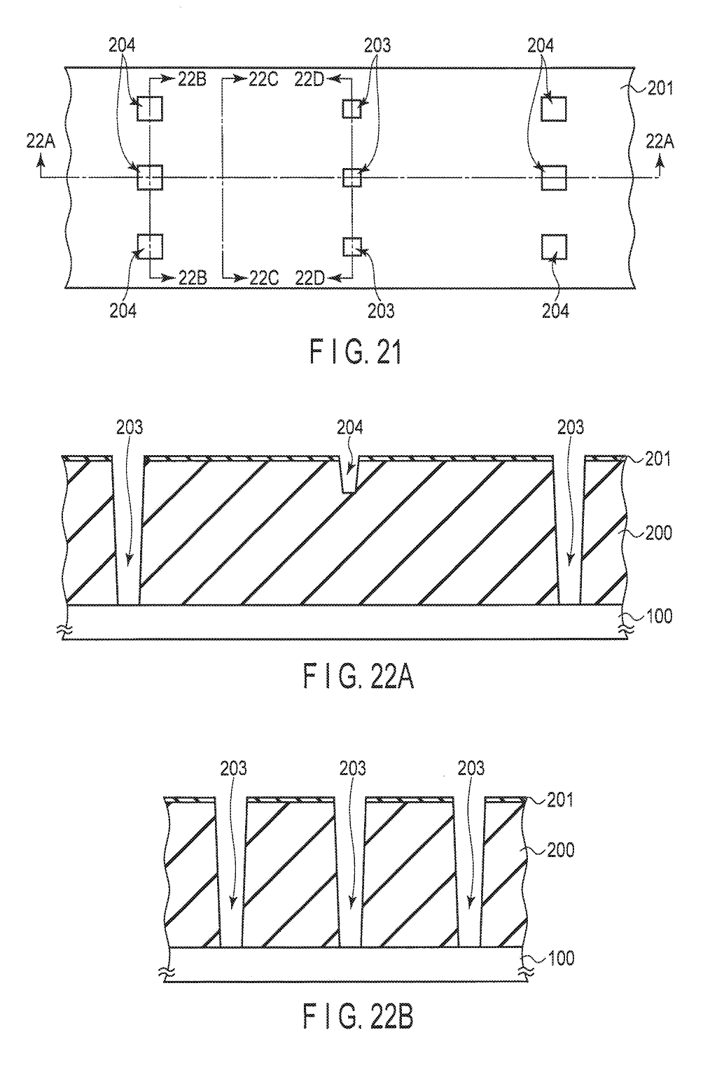

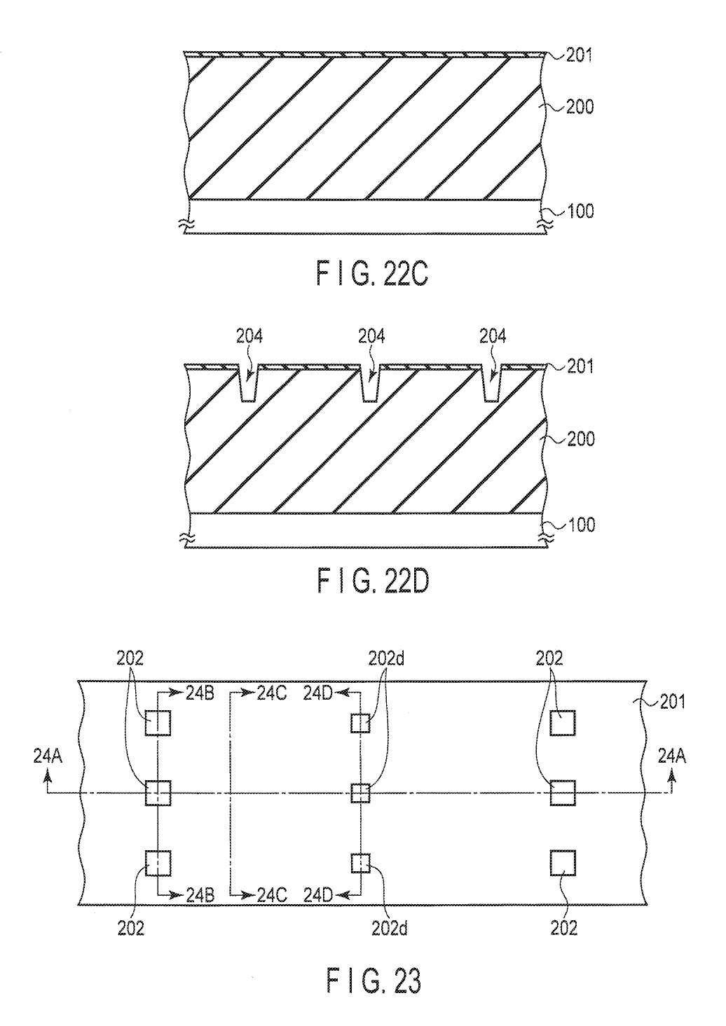

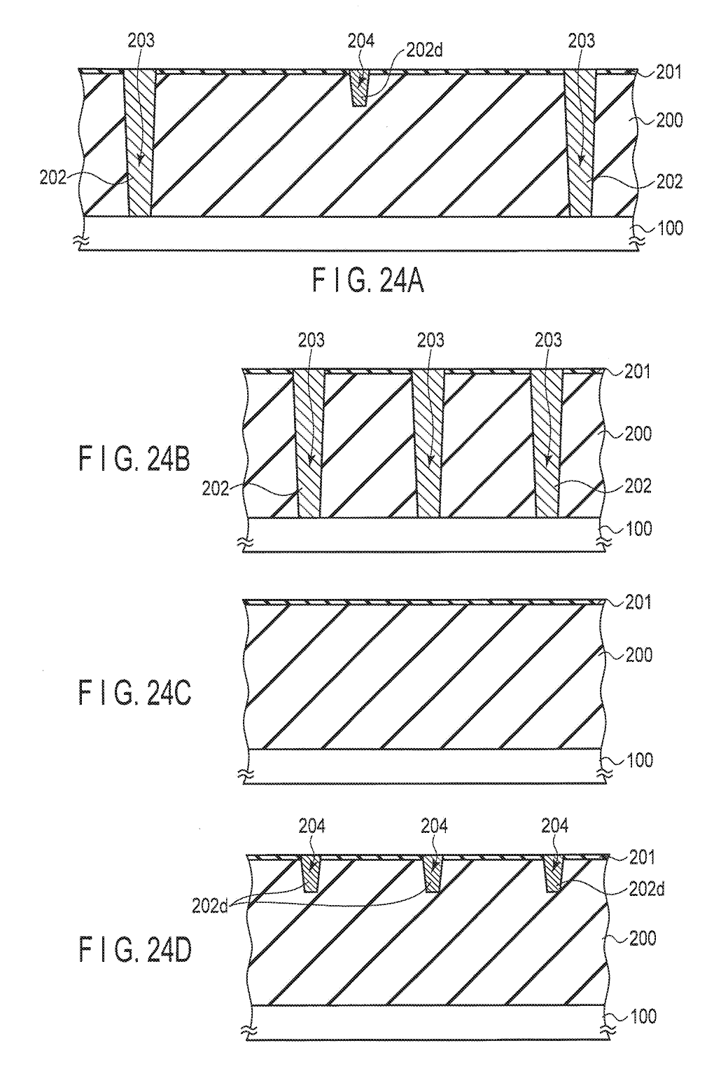

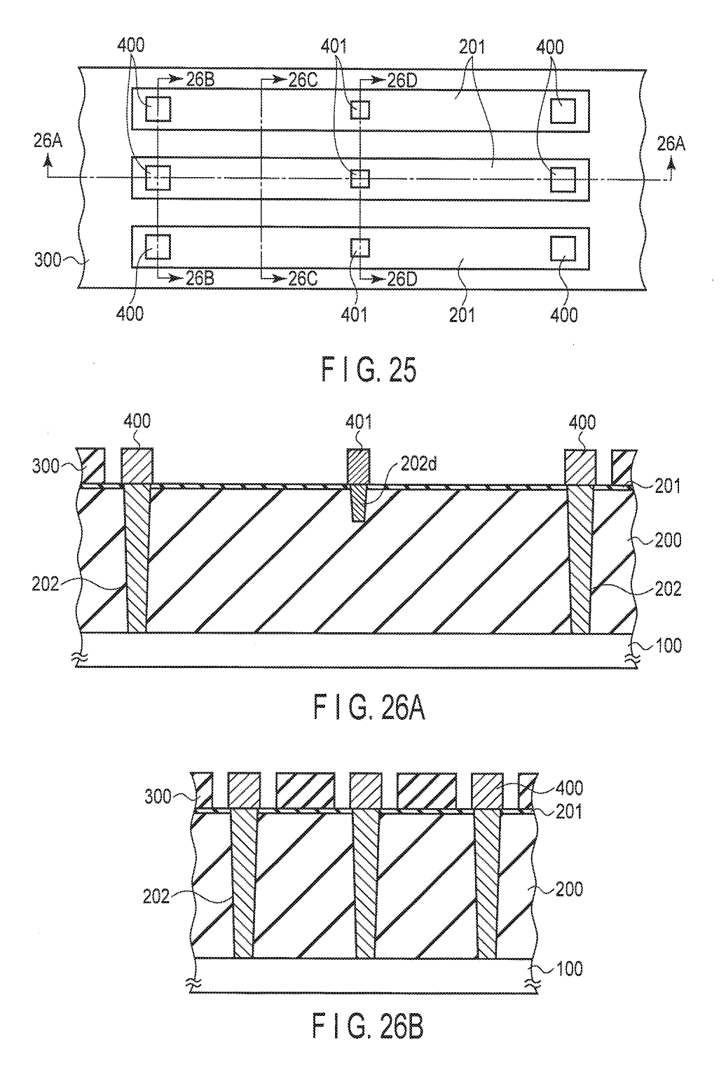

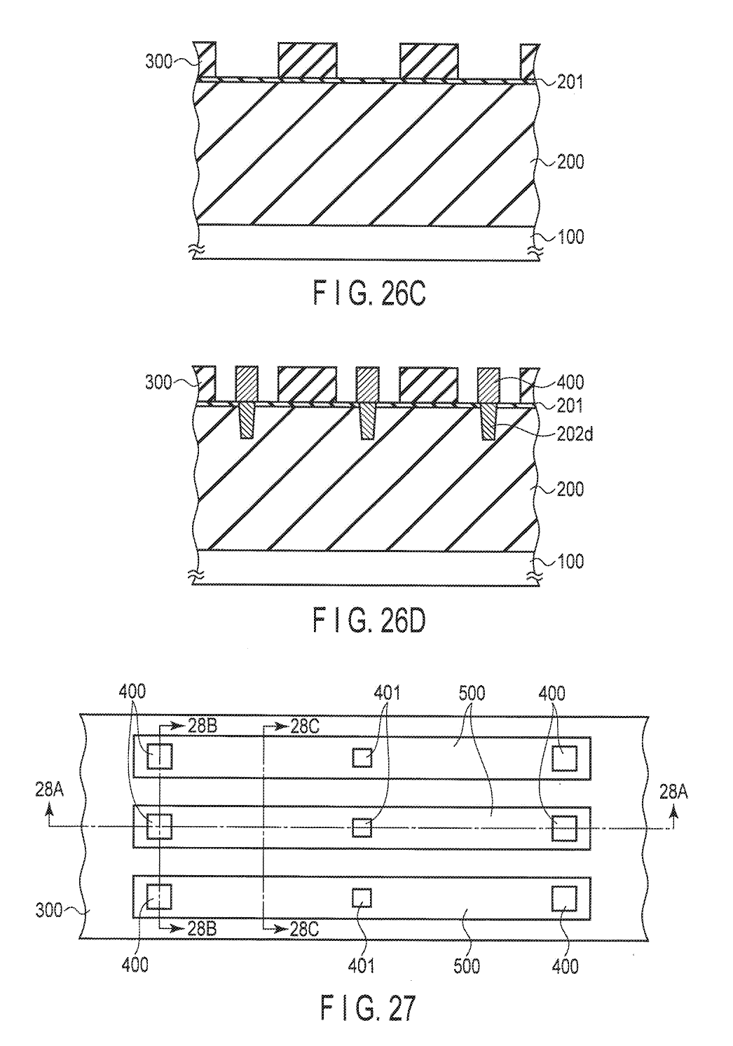

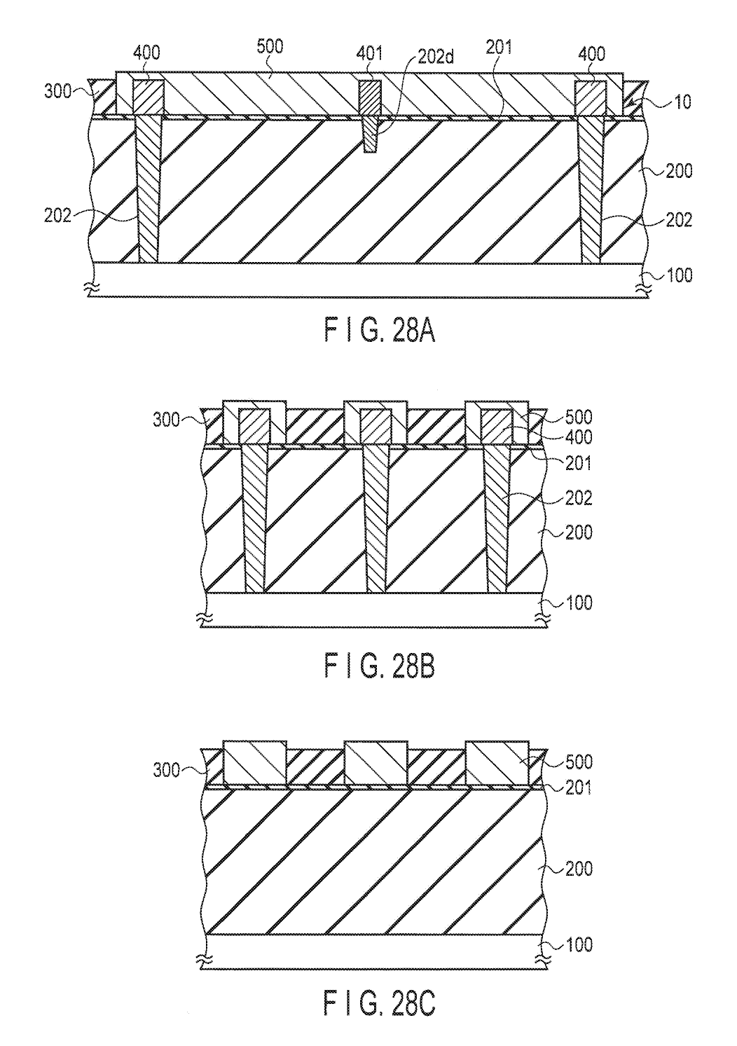

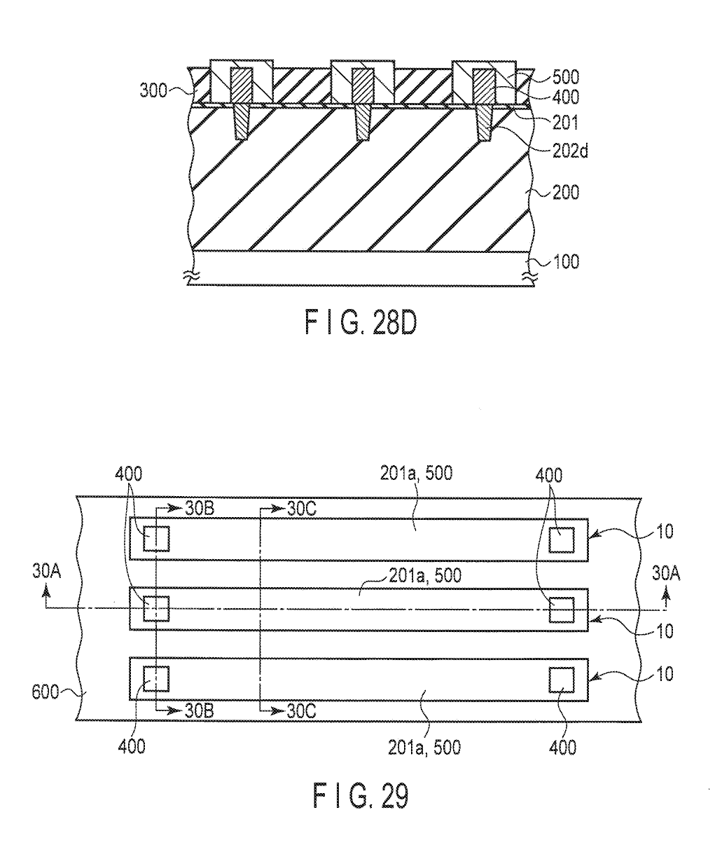

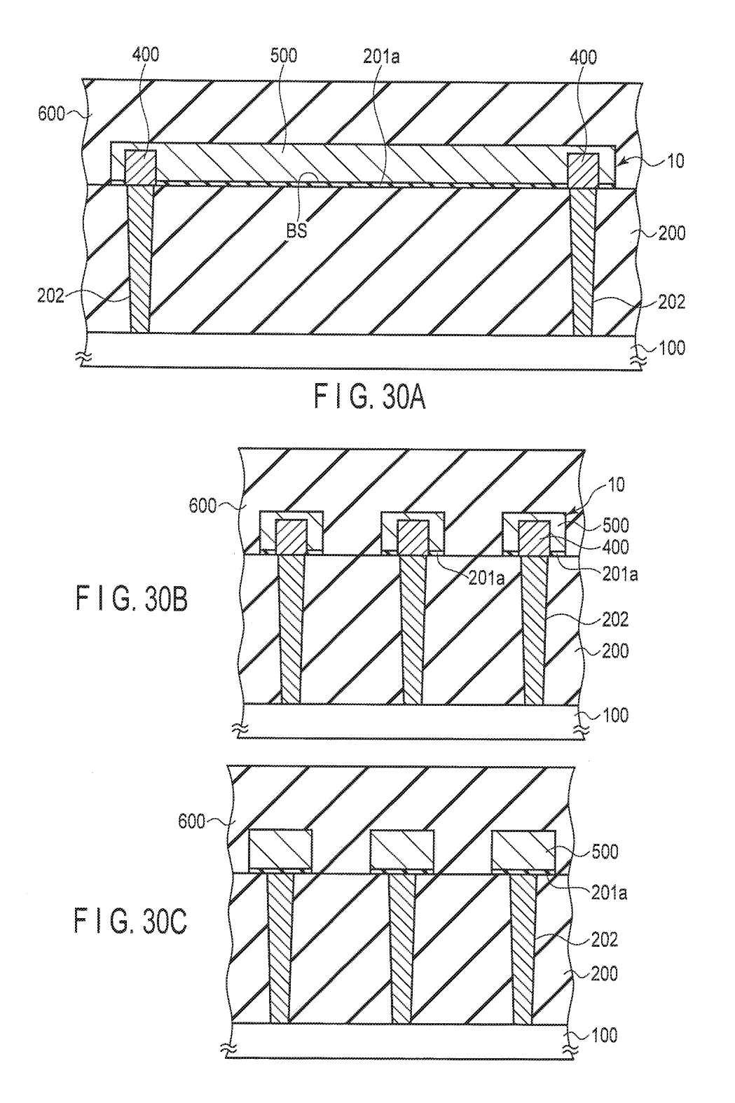

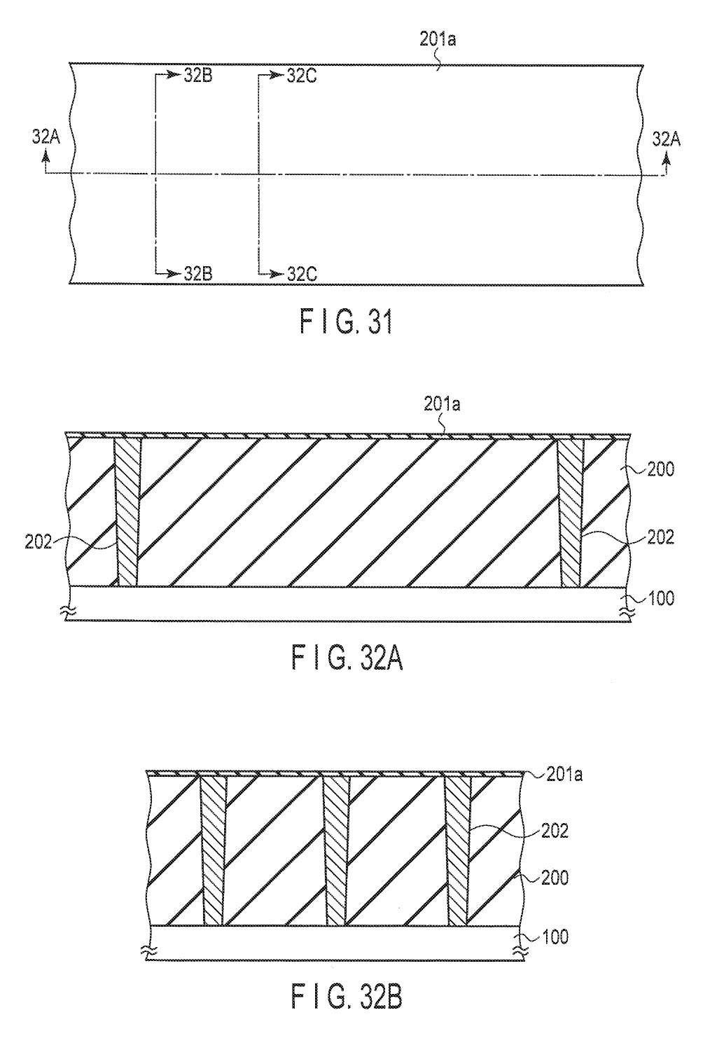

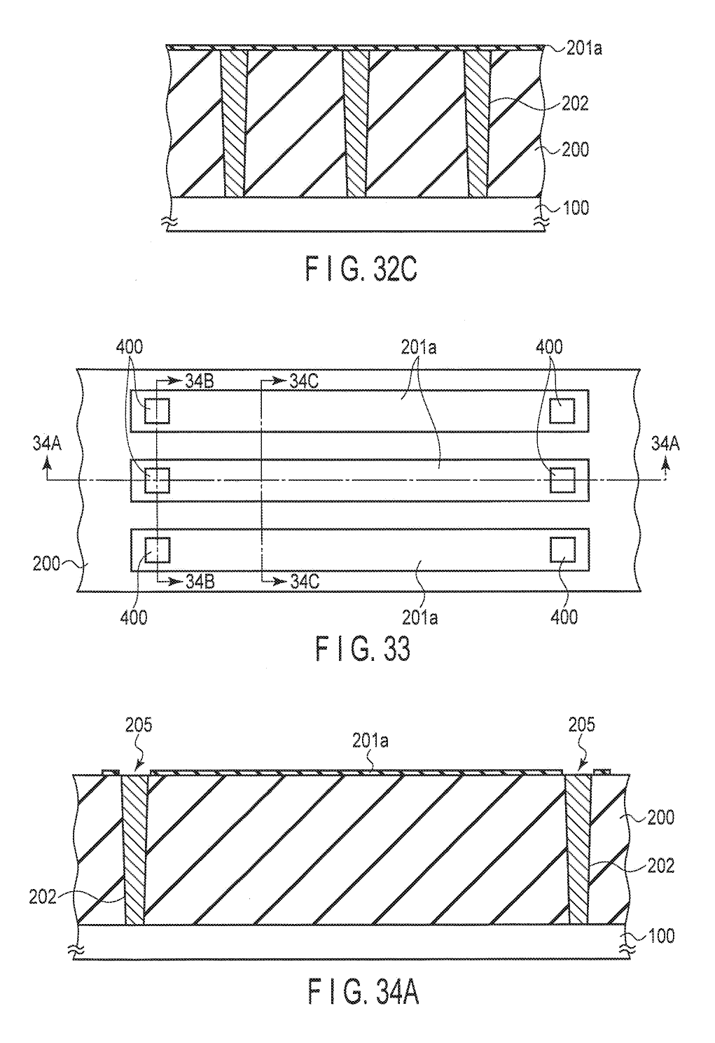

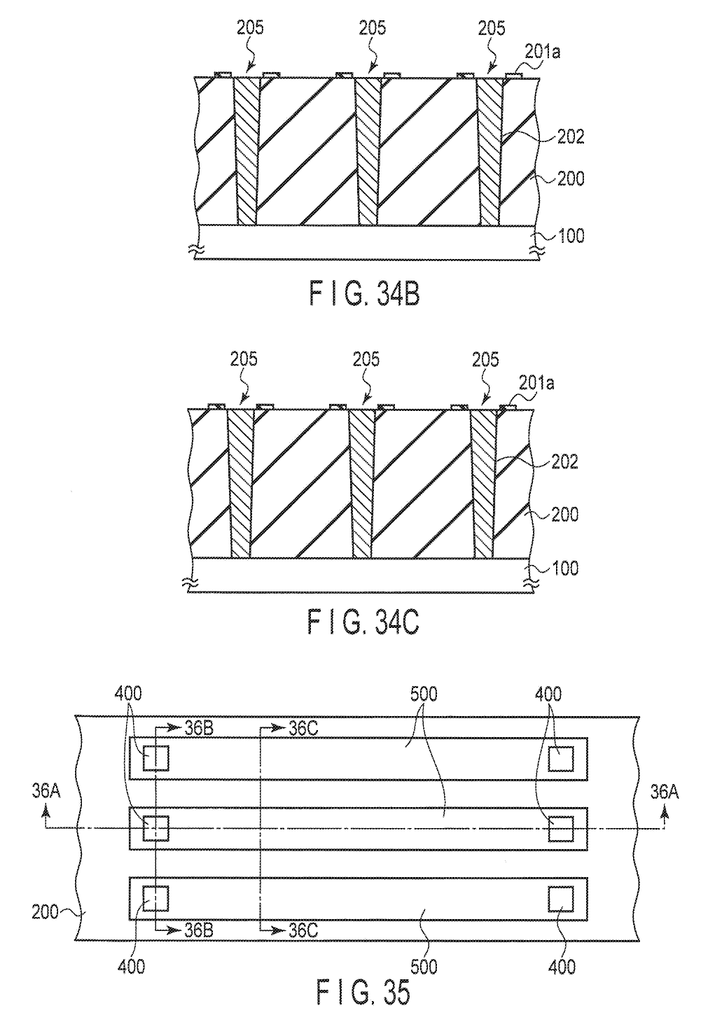

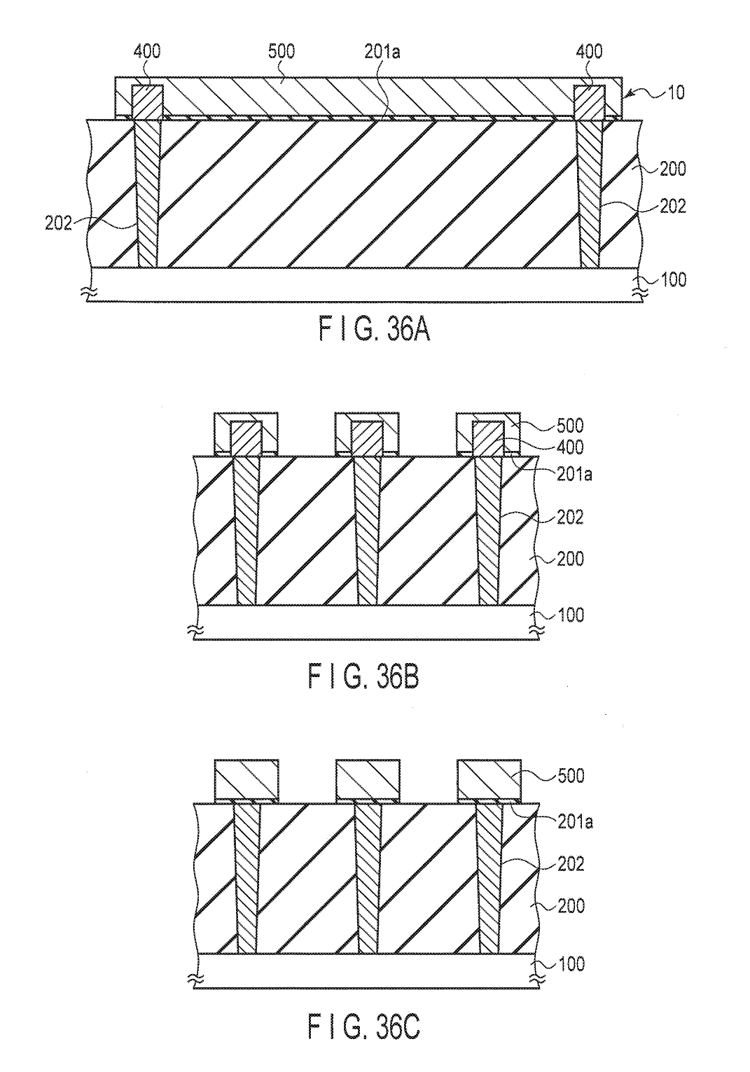

FIG. 3 is a plan view illustrating the method of manufacturing the semiconductor device of the present embodiment. FIGS. 4A, 4B and 4C are sectional views taken along dashed-dotted lines 4A-4A, 4B-4B and 4C-4C of FIG. 3, respectively. Such a relationship between the plan view and the sectional views is also established between a plan view of FIG. 5 and a sectional views of FIGS. 6A to 6C; between a plan view of FIG. 7 and sectional views of FIGS. 8A to 8C; between a plan view of FIG. 9 and sectional views of FIGS. 10A to 100; and between a plan view of FIG. 11 and sectional views of FIGS. 12A to 12C.

[FIG. 3, FIGS. 4A to 4C]

An interlayer insulating film 200 is formed on the substrate 100. The substrate 100 includes, for example, a semiconductor substrate such as a silicon substrate. An element device such as a MOS transistor or a capacitor is formed on the semiconductor substrate.

The underlayer 201 is formed on the interlayer insulating film 200. Here, the underlayer 201 is formed of an insulating material, for example, aluminum oxide.

[FIG. 5, FIGS. 6A to 6C]

Connection holes 203 are formed through the underlayer 201 and the interlayer insulating film 200 down to the substrate 100, and then a conductive film 202 to be processed into plugs is formed on a region including the underlayer 201 such that the connection holes 203 are filled with conductive film. A material of the interlayer insulating film 200 is, for example, tetraethyl orthosilicate (TEOS). A material of the conductive film 202 is, for example, Cu, Al or W, or an alloy including at least one of Cu, Al or W.

[FIG. 7, FIGS. 8A to 8C]

A chemical mechanical polishing (CMP) process is applied to the conductive film 202 and the underlayer 201 in order to remove the conductive film 202 formed outside the connection holes 203, and planarize the surfaces of the conductive 201 and the underlayer film 202. After the CMP process, the conductive film 202 has a plug shape. The conductive film 202 after the CMP process will be hereinafter referred to as the plug 202

Note that, depending on the material of the plug 202, the material (for example, Cu) may be diffused into the interlayer insulating film 200. Such a diffusion is prevented by coating the bottom and the side surface of the plug 202 with a barrier metal film (for example, a TiN film).

After that, the interlayer insulating film (first insulating film) 300 is formed on a region including the underlayer 201 and the plug 202, and then a surface of the interlayer insulating film 300 is planarized by CMP process.

[FIG. 9, FIGS. 10A to 10C]

A photolithography process and an etching process are performed to selectively remove the interlayer insulating film 300 in a region corresponding to a graphene interconnect which is to be formed later. As a result, the upper surfaces of the plug 200 and the underlayer 201 in the region corresponding to the graphene interconnect are exposed. The above-described etching process is, for example, a reactive ion etching (RIE) process.

In the present embodiment, the underlayers (non-catalyst layers) 201 of the graphene interconnects 10 are different portions of the same single underlayer.

Next, the catalyst layer 400 is formed on the upper surface of the plug 202, and catalyst layer 400 is connected to the substrate via the plug 202. In the present embodiment, the catalyst layer 400 is also formed on the upper surface of the underlayer 201 around the upper surface of the plug 202. Therefore, the catalyst layer 400 is formed substantially selectively on the upper surfaces of the plugs 202. In other words, the catalyst layers 400 are formed on the regions corresponding to the connection holes 203 which are formed in a manner to penetrate through the catalyst layer 201 in the process of FIG. 6A.

The method of selectively forming the catalyst layer 400 will be described below.

In the case of employing a Ni layer as the catalyst layer 400, the catalyst layer (Ni layer) 400 is formed substantially selectively by a chemical vapor deposition process (CVD) using, for example, gaseous nickel amidinate as a source gas and gaseous ammonia as a reducing gas. The catalyst layer 400 is formed at a temperature, for example, in a range from 200 to 600° C. Further, The Ni layer is also formed substantially selectively by nickel plating using, for example, a Watts plating bath (an electroplating bath containing nickel sulfate, nickel chloride and boric acid).

It is noted that the material of the catalyst layer 400 is not necessarily deposited selectively on the specific area. For example, in the case of forming a catalyst layer 400 of the same material as that of the plug 202, the catalyst layer 400 may be formed in the following manner. That is, a conductive film to be processed into the catalyst layer 400 is formed, then a surface of the conductive film is planarized by a CMP process, and the conductive film is patterned by using photolithography process and etching process (for example, an RIE process), thereby obtaining the catalyst layer 400.

It is noted that the catalyst layer 400 may be formed in such a manner as to remain within the upper surface of the plug 202.

The catalyst layer 400 has a function to control the height (thickness) of the graphene layer. The height (thickness) of the catalyst layer 400 is, for example, about 10 to about 30 nm.

Here, the height of the upper surface of the catalyst layer 400 is substantially the same as that of the upper surface of the interlayer insulating film 300, but the upper surface of the catalyst layer 400 may be higher than the upper surface of the interlayer insulating film 300. Further, the upper surface of the catalyst layer 400 may be lower than the upper surface of the interlayer insulating film 300. That is, the height of the upper surface of the catalyst layer 400 and the height of the upper surface of the interlayer insulating film 300 may not be in any particular relationship as long as the graphene layer with a necessary height is obtained.

[FIG. 11, FIGS. 12A-12C]

A graphene layer 500 is formed on the underlayer by growing graphene from the side surfaces of the catalyst layer 400 at a low temperature, for example, 650° C. (the lower limit is, for example, 300° C.), by using a low-temperature CVD process with source gas including carbon.

The longitudinal dimension of the graphene layer 500 (interconnect length) may be controlled by the dimension of the long side of the linearly exposed surface of the underlayer 201 in the process of FIG. 9. For example, the interconnect length of the graphene layer 500 may be longer by increasing the dimension of the long side of the exposed surface.

Similarly, the lateral dimension (interconnect width) of the graphene layer 500 may be controlled by the dimension of the short side of the linearly exposed surface of the underlayer 201 in the process of FIG. 9. For example, the interconnect width of the graphene layer 500 may be shorter by decreasing the dimension of the short side of the exposed surface.

Therefore, according to the present embodiment, the graphene interconnect 10 including the graphene layer 500 of the long interconnect length and the narrow interconnect width may be easily realized.

Here, graphene does not have width-dependent resistance, ideally. Therefore, even though the interconnect width is reduced by the miniaturization, an increase in the resistance of the graphene interconnect 10 is suppressed. Further, graphene has a long ballistic wavelength of about 100 nm to about 1 μm. Therefore, even though the interconnect length is increased, the increase in the resistance of the graphene interconnect 10 is also suppressed. In order to suppress the increase in the resistance of the graphene interconnect 10, the interconnect width of the graphene interconnect 10 is, for example, one-tenth or less of the interconnect length of the graphene interconnect.

A bit line is an example of the interconnect with the narrow width and the long length. The graphene interconnect 10 is applicable to the bit line.

In order to further reduce the resistance of the graphene layer 500, impurities may be added to the graphene layer 500. For this purpose, the impurities may be added in the above-described source gas. Alternatively, a treatment such as annealing may be applied to the graphene layer 500 in an atmosphere containing the impurities, which is performed after the graphene layer 500 is formed. The impurities includes, for example, chemical element of group 14, group 15, group 16 or group 17. More specifically, the impurities includes N, Cl or Br, or chemical compound containing N, Cl or Br. The impurities may also contain metals such as Fe.

FIG. 13 is a sectional view schematically depicting the structure of the graphene layer 500 within a region surrounded by a broken line in FIG. 12B. The graphene layer 500 is formed into a roll shape in such a manner as to wrap the upper portion of the catalyst layer 400. As a result, the graphene layer 500 is also provided on the upper surface of the catalyst layer 400.

The catalyst layer 400 is not provided on the upper surface of the interlayer insulating film 300, and the graphene layer 500 is formed into the roll shape as described above, thus the graphene layer 500 is not formed on the upper surface of the interlayer insulating film 300.

FIG. 14 is a sectional view schematically depicting a progress of growing of the graphene layer 500 on the underlayer 201 of the embodiment which is free from a catalyst function for graphene.

In general, the underlayer 201 does not have a completely flat surface but has an uneven surface as shown in FIG. 14. Graphene is grown from the side surfaces of the catalyst layer (not shown), and the graphene layer 500 is formed on the underlayer 201. FIG. 14 illustrates graphene growing from left to right, resulting in forming the graphene layer 500. The graphene layer 500 has an uneven surface reflecting the unevenness of the surface of the underlayer 201.

FIG. 15 is a sectional view schematically depicting the graphene layer 500a formed on the underlayer 201a which has a catalyst function for graphene as a comparative example.

The graphene layer 500a is grown in planar directions using a facet of the underlayer 201a as starting point of growth. However, there is a case where the graphene layer 500a is not formed on projected portions 210 of the uneven surface of the underlayer 201a, which provides the possibility that the graphene layer 500a is formed discontinuously. When the graphene layer 500a constituting the interconnect is formed discontinuously, the interconnect will have a break. Such a breaking is suppressed in the present embodiment because the underlayer 202 of the present embodiment does not have the function of catalyst for graphene.

After the graphene layer 500 is formed, the interlayer insulating film (second insulating film) 600 is then formed on the interlayer insulating film 300 and the graphene layer 500, thereby obtaining the semiconductor device depicted in FIGS. 2A to 2C.

As described above, according to the present embodiment, the graphene layer 500 having the long interconnect length and the short interconnect width is easily formed by using the catalyst layer 400 as a starting point of the growth of graphene and by using the underlayer 201 without catalyst function for graphene as an underlayer for the graphene which grows from the catalyst layer 400, thereby providing the semiconductor device comprising the low-resistance graphene interconnect 10.

### Second Embodiment

FIG. 16 is a plan view illustrating a semiconductor device according to a second embodiment. FIGS. 17A, 17B and 17C are sectional views taken along dashed-dotted lines 17A-17A, 17B-17B and 17C-17C of FIG. 16, respectively. Further, FIG. 18 is a sectional view schematically depicting the structure of a graphene layer 500 within a region surrounded by a broken line in FIG. 17B.

The present embodiment is different from the first embodiment in that a cavity 700 is provided between a side surface of the graphene layer 500 and an interlayer insulating film 300. That is, the cavity 700 is provided around the graphene layer.

A capacitance between adjacent graphene interconnects 10 (parasitic capacitance) is reduced by the cavity 700, thereby reducing signal delay (RC delay) in the graphene interconnect 10.

In order to reduce capacitance between the interconnects, the cavities 700 shown in the sections of FIGS. 17B and 17C (sections in a plane perpendicular to the longitudinal direction of the interconnect) are required, but the cavity 700 shown in the section of FIGS. 17A (section in a plane parallel to the longitudinal direction of the interconnect) is not required.

In order to form the cavity 700, the interlayer insulating film 300 requires poor adherence to graphene. For example, an SiO₂ film is used as the interlayer insulating film 300. Further, as an interlayer insulating film 600, an insulating film with small embedding properties is used, for example, a silicon oxycarbide (SiOC) film or an SiO₂ film formed by spin on direct (SOD) method is used. In this way, it is possible to prevent the interlayer insulating film 600 from being formed in the cavities 700. Still further, an insulating layer such as an Al₂O₃ layer may be used as the underlayer 201 for instance. Still further, an SiO₂ film may be used as the interlayer insulating film 200 for instance, which is formed by a CVD process using tetraethyl orthosilicate (TEOS) as a source gas. Still further, a W plug may be used as a plug 202 for instance.

### Third Embodiment

FIG. 19 is a plan view illustrating a semiconductor device according to a third embodiment.

FIGS. 20A, 20B, 20C and 20D are sectional views taken along dashed-dotted lines 20A-20A, 20B-20B, 20C-20C and 20D-20D of FIG. 19, respectively.

The present embodiment is different from the first embodiment in that a catalyst layer (third catalyst layer) 401 is further provided between two catalyst layers 400. The reason will be described below.

Graphene is grown from the catalyst layer 400 to form a graphene layer 500. Therefore, as the distance between two plugs 202 increases, it requires more time for graphene to grow into the graphene layer 500 which connects the two plugs 202.

Further, depending on process conditions of the device using the graphene layer 500, it is necessary to grow graphene at a low temperature (for example, lower than 300° C.). Again, it requires more time for graphene to grow into the graphene layer 500.

In view of this, the third catalyst layer 401 capable of growing graphene is provided between the two catalyst layers 400, thereby shortening the time required for graphene to grow into the graphene layer 500

Note that, in the present embodiment, the dimension of the third catalyst layer 401 in the longitudinal direction of the interconnect is less than the dimension of the catalyst layer 400 in the longitudinal direction of the interconnect. In this way, an increase in the resistance of the graphene interconnect 10 is suppressed. Further, in the present embodiment, the volume of the third catalyst layer 401 is less than the volume of the catalyst layer 400.

When an increase in the resistance of the third catalyst layer 401 is not too serious to cause an undesirable effect, the dimension of the third catalyst layer 401 in the longitudinal direction of the interconnect may be the same as the dimension of the catalyst layer 400 in the longitudinal direction of the interconnect, or the dimension of the third catalyst layer 401 in the longitudinal direction of the interconnect may be greater than the dimension of the catalyst layer 400 in the longitudinal direction of the interconnect.

The semiconductor device of the present embodiment comprises a dummy plug (third plug) 202d provided under the catalyst layer 401. The dummy plug 202d does not penetrate through the interlayer insulating film 200, and the lower surface of the dummy plug 202d is not connected to the substrate 100. That is, the dummy plug 202d fails to connect the catalyst layer 401 with the substrate 100, and thus the dummy plug 202d does not have a function to electrically connect a layer below the dummy plug 202d and .a layer above the dummy plug 202d. In the present embodiment, the catalyst layer 401 is provided on the upper surface of the dummy plug 202d, and the upper surface of the underlayer 201 around the upper surface of the dummy plug 202d.

An exemplary method of manufacturing the semiconductor device of the present embodiment will be described below.

FIG. 21 is a plan view illustrating the method of manufacturing the semiconductor device of the present embodiment. FIGS. 22A, 22B, 22C and 22D are sectional views taken along dashed-dotted lines 22A-22A, 22B-22B, 22C-22C and 22D-22D of FIG. 21, respectively. Such a relationship between the plan view and the sectional views is also established between a plan view of FIG. 23 and sectional views of FIGS. 24A to 24D; between a plan view of FIG. 25 and sectional views of FIGS. 26A to 26D; and between a plan view of FIG. 27 and sectional views of FIGS. 28A to 28D.

[FIG. 21, FIGS. 22A to 22D]

After the step of FIG. 3 and FIGS. 4A to 4C, a connection holes 203 are formed through an interlayer insulating film 200 and an underlayer 201 down to a substrate 100 by using photolithography process and etching process. Subsequently, grooves 204 are formed through the underlayer 201 and halfway through the interlayer insulating film 200 by using photolithography process and etching process.

Conversely, the connection holes 203 may be formed after the grooves 204 are formed.

[FIG. 23, FIGS. 24A to 24D]

A conductive film to be processed into the plug 202 and the dummy plug 202d is formed to fill the connection holes 203 and the groove 204, and then a CMP process is performed to remove the conductive film on a region outside the connection holes 203 and the groove 204, thereby forming the plugs 202 and the dummy plug 202d in the connection holes 203 and the trench 204, respectively.

[FIG. 25, FIGS. 26A to 26D]

Photolithography process and etching process are performed to remove a portion of the interlayer insulating film 300 corresponding to a region on which the graphene interconnect is to be formed. The removal of the portion of the interlayer insulating film 300 results in exposing the upper surfaces of the plugs 202, the dummy plug 202d and the underlayer 201 corresponding to a region on which the graphene interconnect is to be formed. After that, the catalyst layer 400 and the catalyst layer 401 are formed substantially selectively on the upper surface of the plug 202 and the upper surface of the dummy plug 202d, respectively. In the present embodiment, the catalyst layer 400 is also formed on the underlayer 201 around the upper surface of the plug 202, and the third catalyst layer 401 is also formed on the underlayer 201 around the upper surface of the dummy plug 202d. However, the catalyst layer 400 and the catalyst layer 401 may be formed in such a manner as to remain within the upper surface of the plug 202 and the upper surface of the dummy plug 202d.

In a case where the catalyst layers 400 and 401 are not formed selectively, the dummy plug 202d may be omitted. In this case, the catalyst layers 400 and 401 are obtained by forming a catalyst layer to be processed into the catalyst layers 400 and 401, and then patterning the catalyst layer by using photolithography process and etching process.

[FIG. 27, FIGS. 28A to 28D]

With the use of a low-temperature CVD process using a source gas including carbon, graphene is grown form the side surfaces of the catalyst layers 400 and 401, thereby forming the graphene layer 500.

After the graphene layer 500 is formed, an interlayer insulating film 600 is formed on the interlayer insulating film 300 and the graphene layer 500, thereby obtaining the semiconductor device shown in FIG. 19 and FIGS. 20A to 2D.

### Fourth Embodiment

FIG. 29 is a plan view illustrating a semiconductor device according to a fourth embodiment. FIGS. 30A, 30B and 30C are sectional views taken along dashed-dotted lines 30A-30A, 30B-30B and 30C-30C of FIG. 29, respectively.

The present embodiment is different from the first to third embodiments in that an underlayer 201a has a conductive property. Therefore, a graphene layer 10a does not affect the parasitic capacitance and the breakdown voltage. In addition, the employment of the underlayer 201a having the conductive property, the resistance of the graphene interconnect 10a is reduced. A material of the underlayer 201a is, for example, titanium nitride or metal nitride, which more easily adheres to the graphene than silicon nitride does.

An exemplary method of manufacturing the semiconductor device of the present embodiment will be described below.

FIG. 31 is a plan view illustrating the method of manufacturing the semiconductor device of the present embodiment. FIGS. 32A, 32B and 32C are sectional views taken along dashed-dotted lines 32A-32A, 32B-32B and 32C-32C of FIGS. 31, respectively. Such a relationship between the plan view and the sectional views is also established between a plan view of FIG. 33 and sectional views of FIGS. 34A to 34C; and between a plan view of FIG. 35 and sectional views of FIGS. 36A to 36C.

[FIG. 31, FIG. 32A to 32C]

An interlayer insulating film 200 is formed on a substrate 100, and a plug 202 is formed in the interlayer insulating film 200. After that, a conductive layer 201a is formed on the interlayer insulating film 200 and the plug 202.

[FIG. 33, FIGS. 34A to 34C]

Photolithography process and etching process are applied to the conductive layer 201a to form through holes 205 which expose upper surfaces of the plugs 202 and, a plurality of regions of the upper surface of the interlayer insulating film 200 around the upper surfaces of the plugs 202, and then the conductive layer 201a is divide into layers such that the layers correspond to the graphene interconnects. The layers obtained by dividing the conductive layer 201a will be hereinafter referred to as underlayers 201a.

Here, if the graphene interconnects are formed on the conductive layer 201 with the shape in FIG. 31 which illustrates the step before the dividing, the graphene interconnects will short-circuit. On the other hand, in the present embodiment, the underlayer 201a of each of the graphene interconnects 10 is an independent underlayer. In other words, the number of the graphene interconnects is same as the number of the underlayers 201a, and different graphene interconnect 10 includes different underlayer 201a, and the graphene interconnects 10 (graphene layers 500) and the underlayer 201a have a one-to-one correspondence.

[FIG. 35, FIGS. 36A to 36C]

A catalyst layer 400 is formed on the upper surface of the plug 202 and the plurality of regions of the upper surface of the interlayer insulating film 200 around the upper surface of the plug 202. In other words, the catalyst layers 400 are formed on the regions corresponding to the through holes 205 which are formed in the process of FIGS. 34A to 34C.

Subsequently, graphene is grown from the side surfaces of the catalyst layer 400, thereby forming a graphene layer 500.

After the graphene layer 500 is formed, an interlayer insulating film 600 is formed on the interlayer insulating film 200 and the graphene layer 500, thereby obtaining the semiconductor device depicted in FIG. 29 and FIGS. 30A to 30C.

In the first to third present embodiments, the insulating layer to be processed into the underlayer 201 may be divided into layers corresponding to the graphene interconnects in a manner similar to that of the present embodiment. In this way, the parasitic capacitance between the graphene interconnects can be reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a substrate; and
a first interconnect on the substrate, the first interconnect comprising:
a first catalyst layer capable of growing graphene;
a graphene layer in contact with a side surface of the first catalyst layer; and
a non-catalyst layer in contact with a bottom surface of the graphene layer, and incapable of growing graphene.

2. The device of claim 1, wherein the first catalyst layer is in non-contact with the bottom surface of the graphene layer.

3. The device of claim 1, wherein the non-catalyst layer has an insulating property.

4. The device of claim 3, wherein the non-catalytic layer contains an oxide of a material of the first catalytic layer.

5. The device of claim 3, further comprising a first plug penetrating through the non-catalyst layer.

6. The device of claim 3, further comprising a second interconnect comprising:
a first catalyst layer corresponding to the first catalyst layer of the first interconnect;
a graphene layer corresponding to the graphene layer of the first interconnect; and
a non-catalyst layer corresponding to the non-catalyst layer of the first interconnect,
wherein the non-catalyst layer of the first interconnect and the non-catalyst layer of the second interconnect are different portions of one non-catalyst layer.

7. The device of claim 1, wherein the non-catalyst layer has a conductive property.

8. The device of claim 7, wherein the non-catalytic layer contains titanium nitride or tantalum nitride.

9. The device of claim 7, wherein the first catalyst layer penetrates through the non-catalyst layer.

10. The device of claim 9, further comprises a first plug under the first catalyst layer and in contact with the first catalyst layer.

11. The device of claim 7, further comprising a second interconnect comprising:
a first catalyst layer corresponding to the first catalyst layer of the first interconnect;
a graphene layer corresponding to the graphene layer of the first interconnect; and
a non-catalyst layer corresponding to the non-catalyst layer of the first interconnect,
wherein the non-catalyst layer of the first interconnect is separated from the non-catalyst layer of the second interconnect.

12. The device of claim 1, wherein the first interconnect further comprises a second catalyst layer, and the graphene layer is further in contact with a side surface of the second catalyst layer.

13. The device of claim 12, wherein the first and second catalyst layers comprise at least one of cobalt (Co), nickel (Ni), iron (Fe), ruthenium (Ru), copper (Cu), an alloy containing Co, Ni, Fe, Ru or Cu, and carbide of Co, Ni, Fe, Ru or Cu.

14. The device of claim 12, wherein the second catalyst layer is in non-contact with the bottom surface of the graphene layer.

15. The device of claim 12, further comprising a second plug under the second catalyst and in contact with the second catalyst layer.

16. The device of claim 15, wherein the first catalyst layer is connected to the substrate via the first plug, and the second catalyst layer is connected to the substrate via the second plug.

17. The device of claim 16, further comprising a third catalyst layer in the graphene layer.

18. The device of claim 17, further comprising a third plug under the third catalyst layer and in contact with the third catalyst and failing to connect the third catalyst layer with the substrate.

19. The device of claim 1, further comprising a cavity around the graphene layer.

20. A method of manufacturing a semiconductor device, comprising:
forming a non-catalyst layer on the substrate;
forming a through hole in the non-catalyst layer;
forming a catalyst layer on a region corresponding to the through hole of the non-catalyst layer; and
forming a graphene layer on the non-catalyst layer by growing graphene using the catalyst layer as a starting point of the growth.
